(19) United States
(12) Patent Application Publication
(10) Pub. No.: US 2015/0238906 A1
(43) Pub. Date: Aug. 27, 2015

(54) MEMBRANES WITH VERTICALLY CORRELATED CARBON NANOTUBES, AND METHODS OF MAKING AND USING SAME

(71) Applicants: University of Rochester, Rochester, NY (US); The Research Foundation for The State University of New York, Albany, NY (US)

(72) Inventors: Todd Krauss, Pittsford, NY (US); Gregory Pilgrim, Rochester, NY (US); Steven M. Pilgrim, Almond, NY (US)

(21) Appl. No.: 14/632,323

(22) Filed: Feb. 26, 2015

Related U.S. Application Data
(60) Provisional application No. 61/945,439, filed on Feb. 27, 2014.

(51) Int. Cl. B01D 63/06; C25B 13/02; C25B 13/04; B01D 46/54

(52) U.S. Cl. CPC B01D 63/06; B01D 46/543; C25B 13/02; C25B 13/04; B01D 2319/04

(57) ABSTRACT

A free-standing membrane comprises a plurality of vertically aligned carbon nanotubes, each of the plurality of vertically aligned carbon nanotubes having a first terminus at a first side of the membrane and a second terminus at a second side of the membrane. The first and second terminuses are exposed. The free-standing membrane comprises a non-conducting, inert filler material disposed in the interstitial space between the nanotubes such that a barrier to electron, proton, and/or ion transport is formed, and so that conduction of electrons, protons, and/or ions only occurs through the plurality of vertically aligned carbon nanotubes and not through the inert filler material. Methods for fabricating the membrane comprise nanotube growth, epoxy coating, and exposure of the terminuses of the nanotubes.

### CROSS-REFERENCE TO RELATED APPLICATIONS

This application claims priority to and the benefit of co-pending U.S. provisional patent application Ser. No. 61/945,439, entitled Membranes with Vertically Correlated Carbon Nanotubes, and Methods of Making and Using Same, filed Feb. 27, 2014, which is incorporated herein by reference in its entirety.

### STATEMENT REGARDING FEDERALLY SPONSORED RESEARCH OR DEVELOPMENT

The disclosed invention was made with government support under grant number DE-FG02-09ER16121 awarded by the Department of Energy. The government has certain rights in the invention.

### TECHNICAL FIELD

The present invention relates to free-standing membranes of carbon nanotubes. The invention also relates to membranes that can simultaneously transport protons and electrons under aqueous conditions. The invention further relates to methods for making free-standing membranes of carbon nanotubes.

### BACKGROUND

Many potential uses exist for a membrane that can simultaneously transport protons and electrons under aqueous conditions. During photosynthesis, for example, biological systems, notably Photosystems I and II, use coupled transport of electrons and protons to move components for reduced chemical fuels through membranes while maintaining charge balance. Analogous inorganic systems supporting transport of protons and electrons are of interest for solar fuel technologies, i.e., the generation of hydrogen gas by photocatalyzed water splitting during artificial photosynthesis. Among the many technical requirements of such a system is a membrane capable of transporting both photogenerated electrons and the ionic components of the desired chemical fuel, i.e. protons. Although single materials that transport both protons and electrons have been reported, including tungsten oxides and various ceramics, they typically require operating temperatures in excess of 300° C. and are not compatible with aqueous hydrogen production systems. Nanostructured membranes that incorporate a mixture of electron-conducting and proton-conducting materials provide the necessary functionality. Their fabrication, however, can be complex and expensive. Other heterogeneous systems, such as disordered polymer systems, make attachment of molecules to one polymer (and therefore one system—electronic or ionic) difficult as polymers are intermixed. Catalyst molecules intended to interact with the electronic system can only be attached to areas of the membrane where PEDOT:PSS is exposed on the surface. In the case of silicon nanowire arrays and previous carbon nanotube columns, fabrication requires photolithography steps before deposition of catalysts for array growth and, in the case of silicon nanowire array fabrication, the use of hydrofluoric acid.

### SUMMARY

A free-standing membrane is provided comprising:
a plurality of vertically aligned carbon nanotubes, each of the plurality of vertically aligned carbon nanotubes having:
   a first terminus at a first side of the membrane,
   a second terminus at a second side of the membrane, wherein the first terminus and the second terminus are exposed,
   a length of at least 1 nm, and
      an inner diameter of 0.13 nm to 100 nm; and a non-conducting, inert filler material disposed in interstitial space between the nanotubes such that a barrier is formed, wherein the membrane has a thickness between 1 nm and 1 cm.

In an embodiment of the membrane, the membrane simultaneously conducts electrons and transports ions.

In an embodiment of the membrane, wherein the ions are protons, potassium ions, or lithium ions.

In an embodiment of the membrane, the membrane has an area of 5 nm² to 300 cm².

In an embodiment of the membrane, the membrane has a length of 5 nm to 50 cm and/or a width of 5 nm to 50 cm.

In an embodiment of the membrane, at least a portion of a surface of at least one of the vertically aligned nanotubes has disposed thereon functional groups selected from the group consisting of carboxylic acid groups, acyl halides (e.g., acyl chloride), esters, anhydrides, ketones, and combinations thereof.

In an embodiment of the membrane, at least a portion of a surface of at least one of the vertically aligned nanotubes has immobilized thereon at least one light absorbing material (e.g., a light absorbing molecule), catalytic material (e.g., a catalytic molecule), or a combination thereof.

A device is provided comprising the free-standing membrane disclosed herein.

In one embodiment of the device, the device is a photoelectrochemical cell, a sieve, a sensor, or a filter.

A method is provided for making a free-standing membrane comprising:
a) providing a catalyst and a substrate;
b) depositing the catalyst on at least a portion of the substrate, wherein the deposited catalyst is capable, upon exposure of the substrate on which the catalyst is deposited to a carbon nanotube precursor, of catalyzing the formation of vertically aligned carbon nanotubes on the substrate;
c) annealing the substrate on which the catalyst is deposited from b) in an inert atmosphere;
d) annealing the substrate from c) in a hydrogen gas atmosphere;
e) exposing the substrate from d) to an atmosphere comprising CNT precursor and an inert gas, thereby catalyzing formation, from the CNT precursor, of a plurality of vertically aligned carbon nanotubes, wherein each carbon nanotube of the plurality of vertically aligned carbon nanotubes has a substrate terminus and free terminus;
f) coating the substrate from e) with an inert filler material such that the free terminuses of the carbon nanotubes in the plurality remain exposed and the inert filler material forms a barrier on the substrate; and
g) removing the substrate and the deposited catalyst, thereby exposing the substrate terminuses of the plurality of carbon nanotubes, and thereby forming the free-standing membrane.

In embodiments of the method and of the membrane, the substrate and deposited catalyst are not removed (e.g., for use as an electrode).

In another embodiment of the method, the method comprises functionalizing at least a portion of a surface of a carbon nanotube in the plurality.

In another embodiment of the method, the functionalizing of at least a portion of a surface of a carbon nanotube in the plurality can occur before or after removing the substrate and deposited catalyst.

In another embodiment of the method, the membrane simultaneously conducts electrons and transports ions.

In another embodiment of the method, the ions are protons, potassium ions, or lithium ions.

In another embodiment of the method, the membrane has an area of 5 nm² to 300 cm².

In another embodiment of the method, the membrane has a length of 5 nm to 50 cm and/or a width of 5 nm to 50 cm.

In another embodiment of the method, at least a portion of a surface of at least one of the vertically aligned nanotubes has disposed thereon functional groups selected from the group consisting of carboxylic acid groups, acyl halides (e.g., acyl chloride), esters, anhydrides, ketones, and combinations thereof.

In another embodiment of the method, at least a portion of a surface of at least one of the vertically aligned nanotubes has immobilized thereon at least one light absorbing material (e.g., a light absorbing molecule), catalytic material (e.g., a catalytic molecule), or a combination thereof.

### BRIEF DESCRIPTION OF THE DRAWINGS

Embodiments are described herein with reference to the accompanying drawings, in which similar reference characters denote similar elements throughout the several views. It is to be understood that in some instances, various aspects of the embodiments may be shown exaggerated, enlarged, exploded, or incomplete to facilitate an understanding of the invention.

FIGS. 1A-E. Example of one embodiment of a method for fabricating a VANT (vertically aligned nanotube) membrane. (A) Nanotube array growth on a silicon wafer alumina support and iron catalyst. (B) Epoxy coating. (C) Tip exposure. (D) Removal of wafer and catalyst. (E) Tube opening via ozone treatment. Components are not shown to scale.

FIGS. 2A-B. Images of a VANT membrane. (A) Scanning electron microscope image of vertically aligned NTs. The scale bar is 10 μm and the NTs are approximately 150 μm tall. (B) Nanotube arrays following epoxy impregnation and isopropyl alcohol treatment. Scale bar is 10 μm and approximately 20 μm of NT length are exposed above the bulk. (Inset) Photograph of the final, self-supporting membrane approximately 2.5 cm².

FIG. 3. Temporal evolution of absorption spectra for bromophenol blue indicator during course of proton transport experiments. The peak at 593 nm corresponds to nonprotonated indicator while the peak at 449 nm corresponds to protonated indicator. Note the isosobestic point at around 500 nm. Proton crossing time goes from 0 to 225 minutes (dotted line to dashed line) in 15-minute intervals. Inset depicts change in concentration of protonated (dotted line) and nonprotonated (dashed line) indicator.

FIG. 4. Comparison of the disappearance of bromophenol blue indicator peak at 593 nm corresponding to a decrease in nonprotonated indicator species. Rate of disappearance, proportional to rate of proton crossing, is roughly twice as large in NAFION® (DuPont) (squares) as in NT membranes (circles).

FIG. 5. Peak photocurrent generated in a VANT membrane upon irradiation with 440 nm light. Troughs occur when the light source was physically blocked, preventing irradiation.

FIG. 6. Graphical representation of function of VANT membrane.

FIG. 7. Transmission electron microscopic (TEM) image of a multi-walled nanotube grown according to the methods disclosed herein. Walls (15-20 nm) are visible. Inner diameter is 5-7 nm, outer diameter is 15-20 nm.

FIG. 8. One current versus voltage curve for a VANT membrane measured along the long nanotube axis showing the linear relationship between current and voltage. Voltage step size is 0.0001 V.

FIG. 9. Drawing depicting the experimental apparatus for the proton membrane crossing experiment in Example 1. Solution volumes were 20 mL. Voltage was maintained using an HP 6284A DC power supply.

FIG. 10. Peak quantum dot (QD) absorbance of visible light (bottom graph as it originates at left of plot) corresponds to peak photocurrent production (top graph as it originates at left of plot). Absorbance of more light means more photogenerated electrons.

### DETAILED DESCRIPTION

VANT Membranes

The present disclosure provides free-standing vertically aligned nanotube (e.g., carbon nanotube) (VANT) membranes. Also provided are methods of making and using the VANT membranes.

VANT membranes can be used in applications such as, for example, artificial photosynthesis. The following are some of the advantages of the VANT membranes that are provided. Carbon is inexpensive and readily available, which is a consideration for any large-scale implementation of water splitting systems as an energy solution. The membranes exhibit toughness, both chemical and physical. In the fabrication process, the membranes survive extended contact with both hot, concentrated base (e.g., 8 M KOH at ˜398K) and concentrated acid (e.g., 11 M HCl). Membranes also withstand, for example, the mechanical stress of abrading away the iron catalyst and alumina support. Following all these treatments, the membranes remain whole, flexible and easily manipulated by hand. The membranes use one material, carbon nanotubes (CNTs or carbon NTs), for both electron conduction and proton transport. Growth of carbon nanotube arrays uses catalyst deposition (unpatterned) before growth. No secondary transport material, such as NAFION®/sPSS is used. This yields a savings in complexity as well as an increase in electron and proton conductivity. The VANT membranes provide desirable large surface area and clear points for the attachment of light absorbing or catalytic molecules such as those involved in water splitting.

VANT membranes simultaneously conduct electrons and ions (e.g., protons). As fabricated, these membranes leave the nanotube pi system available not just for electron transport, but also for potential chemical modification, making them adaptable for use as sieves, sensors, or electrodes or in other applications

VANT membranes have a plurality of vertically aligned carbon nanotubes. The nanotubes are sequestered in an inert filler (or binder) material. In an embodiment, the VANT membrane comprises carbon nanotubes and an inert filler material. In another embodiment, the VANT membrane may be constituted of only carbon nanotubes and the inert filler material.

### Carbon Nanotubes (CNT)

The free-standing VANT membrane comprises a plurality of carbon nanotubes. The carbon nanotubes can have a variety of structures. Examples of carbon nanotubes determined to be suitable include, but are not limited to, single-wall nanotubes, multi-wall nanotubes, and doped nanotubes. Mixtures of carbon nanotubes with different (n,m) structure indices can also be used.

In an embodiment, the free-standing membrane comprises a plurality of vertically aligned carbon nanotubes, each of the plurality of vertically aligned carbon nanotubes having a first terminus at a first side of the membrane and a second terminus at a second side of the membrane. The first and second terminuses are exposed. The free-standing membrane comprises a non-conducting, inert filler material disposed in the interstitial space between the nanotubes such that a barrier to electron, proton, and/or ion transport is formed, so that conduction of electrons, protons, and/or ions only occurs through the plurality of vertically aligned carbon nanotubes and not through the inert filler material. By barrier it is also meant that the inert filler material provides a physical barrier (e.g., the inert filler prevents, other than that of the CNTs, ion or electron transport or liquid/solvent transport across the membrane).

In an embodiment, the carbon nanotubes have a length of at least 1 nm, and an inner diameter of 0.13 nm to 100 nm

The carbon nanotubes have dimensions such that ions (e.g., protons, potassium ions, lithium ions, or a combination thereof) can be transported through the lengths of the nanotubes. The nanotubes have exposed terminuses that allow ions to pass through the ends of the nanotubes.

One having skill in the art will recognize that nanotubes of varying lengths can be formed. In various embodiments, the nanotubes have a length of 1 nm to 1 cm, including all integer nm values and ranges therebetween.

One having skill in the art will recognize that nanotubes of varying inner diameters can be formed. In various embodiments, the nanotubes have inner diameters of 0.13 nm to 100 nm, including all integer nm values and ranges therebetween. In another embodiment, the nanotubes have inner diameters of 0.10 nm to 1 nm. In another embodiment, the nanotubes have inner diameters of 1 nm to 50 nm. In another embodiment, the nanotubes have inner diameters of 50 nm to 100 nm.

The carbon nanotubes are generally disposed in the membrane such that one or both terminuses of the nanotubes are located substantially in a plane. By substantially in a plane, it is meant that greater than 80% of the individual tube lengths in the free membrane deviate by less than 20% from the average of the individual tube length in the membrane. In various embodiments, greater than 85, 90, 95, 96, 97, 98, or 99% of the individual tube lengths in the free membrane deviate by less than 20, 15, 10, 5, 4, 3, 2, or 1% from the average tube length in the membrane. In an embodiment, all of the first terminuses and/or second terminuses are in the same plane.

The carbon nanotubes in the plurality of carbon nanotubes are vertically aligned. By vertically aligned it is meant that the carbon nanotubes are substantially parallel to each other and/or substantially aligned to a single axis. By substantially parallel or substantially aligned it is meant that the angle formed by the tube with respect to one of the surfaces formed by the terminuses of the carbon nanotubes (i.e., a side of the membrane on which the carbon nanotube terminuses fall) for greater than 80% of the individual tubes is greater than 45 degrees. In various embodiments, the angle formed by the tube with respect to one of the surfaces formed by the terminuses of the carbon nanotubes for greater than 85, 90, 95, 96, 97, 98, or 99% of the individual tubes is greater than 45, 60, 70, 80, 85, 86, 87, 88, or 89 degrees. For example, in an embodiment, vertically aligned nanotubes (“tubes”) are grown from a catalyst film into an array. The individual nanotubes may be perpendicular to the longest axis of the membrane. The density of carbon nanotubes is, for example, 10¹⁰ nanotubes per cm² of membrane on the low end and 10¹² nanotubes per cm², including all integer values and ranges therebetween.

### VANT Membrane Form Factors

The free-standing membranes can have various form factors (e.g., sizes and shapes). One having skill in the art will recognize that membranes having various form factors can be formed. For example, the membranes can have a thickness (measured between the sides of the membrane on which the carbon nanotubes terminate) of 1 nm to 10,000 μm, including all integer nm and μm values and ranges therebetween. In an embodiment, the membranes can have a thickness of 1 nm to 10 μm, including all integer nm and μm values and ranges therebetween. In another embodiment, the membranes can have a thickness of 10 μm to 5,000 μm, including all integer μm values and ranges therebetween. In another embodiment, the membranes can have a thickness of 5,000 μm to 10,000 μm, including all integer μm values and ranges therebetween. In another embodiment, the membranes can have a thickness of 5 nm to 5,000 μm, including all integer nm and um values and ranges therebetween.

The thickness may vary across the membrane. In an embodiment, the thickness is not uniform across the membrane. The thickness can vary across the range of membrane thickness described herein. For example, the thickness can be controlled by selective CNT growth and/or etching (e.g., selective etching) of the membrane.

One having skill in the art will recognize that membranes having a range of membrane area can be formed. For example, the membranes can have an area of 5 nm² to 300 cm², including all integer nm² and cm² values and ranges therebetween. In another embodiment, the membranes can have an area of 10 nm² to 100 cm², including all integer nm² and cm² values and ranges therebetween. In another embodiment, the membranes can have an area of 10 nm² to 1000 nm², including all integer nm² values and ranges therebetween. In another embodiment, the membranes can have an area of 1 μm² to 1000 μm², including all integer μm² values and ranges therebetween. In another embodiment, the membranes can have an area of 1 mm² to 100 mm², including all integer mm² values and ranges therebetween. In another embodiment, the membranes can have an area of 1 cm² to 300 cm², including all integer cm² values and ranges therebetween.

It is within the purview of one having skill in the art to form the membranes having the desired shape. The membrane can have shapes such as, for example, circular, oval, rectangular, or any other Euclidian shape. For example, the films can be circular and have 4 inch or 6 inch diameter. For example, the membranes can have a length and/or width of 5 nm to 50 cm, including all integer nm and cm values and ranges therebetween. In an embodiment, the membranes can have a length and/or width of 5 nm to 1000 nm, including all integer nm values and ranges therebetween. In another embodiment, the membranes can have a length and/or width of 1 um to 1000 μm, including all integer um values and ranges therebetween. In another embodiment, the membranes can have a length and/or width of 1 mm to 10 mm, including all integer mm values and ranges therebetween. In another embodiment, the membranes can have a length and/or width of 1 cm to 50 cm, including all integer cm values and ranges therebetween.

The membranes can simultaneously conduct electrons and transport protons or ions. For example, the membranes have an electrical conductivity of that is greater than that of the inert filler material to that of a free standing CNT array. The membrane can exhibit ballistic conductance. For example, the membranes transports ions at measurably greater than zero (i.e., no measureable ion transport) to the mass transfer limit

### Inert Filler Material

The free-standing VANT membrane comprises an inert filler material. The inert filler material maintains the vertical orientation of the carbon nanotubes and provides mechanical integrity to the membrane. The inert filler material is non-conducting (i.e., electrically insulating) such that substantially all of the electrical conductivity is carried out by the carbon nanotubes. In an embodiment, no measurable electrical conductivity is carried out through the inert filler material.

The inert filler material forms a barrier such that the only pathway (e.g., ion transport pathway) through the membrane, from one side of the membrane to the other side of the membrane, is through the carbon nanotubes. By barrier it is also meant that the inert filler material provides a physical barrier (e.g., the inert filler prevents, other than that of the CNTs, ion or electron transport or liquid/solvent transport across the membrane).

For example, both sides of the membrane corresponding to the terminuses of the carbon nanotubes are completely sealed (except for the CNT bores). Optionally, in an embodiment, the interstitial space between the two sides of the membrane has no inert filler material filling it. In another embodiment, the inert filler material fully penetrates the interstitial space between the carbon nanotubes.

In an embodiment, the inert filler material does not conduct any measurable electrical current. In various embodiments, greater than 90%, greater than 95%, or greater than 99% of the measurable electrical conductivity is carried out by the carbon nanotubes. In an embodiment, all (100%) of the measurable electrical conductivity is carried out by the carbon nanotubes.

In an embodiment, the inert filler material is chemically inert and physically stable (e.g., resistant to fracture and exhibits toughness). Examples of inert filler materials that can be used include, but are not limited to, chemically resistant epoxies, such as a two-part epoxy (e.g., EPO-TEK®) 301, Epoxy Technology, Inc., Billerica, Mass. 01821), organic polymers (e.g., polystyrene), inorganic polymers (e.g., polydimethylsiloxane), glasses (e.g., soda lime glass), and inorganic materials (e.g., Si₃N₄ and BN). The inorganic materials can be crystalline, polycrystalline, or non-crystalline (e.g., amorphous silicon).

### CNT Functionalization

In various embodiments, the surface of the carbon nanotubes may be functionalized. In an embodiment, at least a portion of a surface of at least one of the vertically aligned nanotubes in the plurality of nanotubes has disposed thereon functional groups selected from the group consisting of carboxylic acid groups, acyl halides (particularly acyl chloride), esters, anhydrides, ketones, and/or combinations thereof. These groups may result from ozone opening of fullerene caps on the carbon nanotubes.

As referred to in this disclosure, the phrase “at least one” means “one or more” or “one or a plurality.”

In another embodiment, at least a portion of a surface of at least one of the vertically aligned nanotubes has tethered (e.g., chemically bonded) thereon, at least one light absorbing materials (e.g., light absorbing molecules), such as quantum dots (e.g., CdSe, CdTe, and PbSe quantum dots) and metal particles (e.g. Au, Ag, Pt, and Pd metal particles), molecular chromophores (e.g., metal compounds and organic dyes), catalytic molecules (e.g., porphyrins), and/or combinations thereof can be used. The membrane can be functionalized with any light absorbing molecule that has a ligand or moiety that can pi stack on the carbon nanotube extended pi structure (or portion thereof) and be in electrical contact with the carbon nanotube. Methods of functionalizing a carbon nanotube surface are known in the art.

### Methods for Making VANT Membranes

Methods are provided for making free-standing VANT membranes. The methods are based on forming carbon nanotubes that are vertically correlated. The methods comprises: nanotube (NT) growth, inert filler material deposition (e.g., epoxy coating), and NT exposure.

In an embodiment, a method for making a free-standing membrane comprises:
a) providing a catalyst and a substrate;
b) depositing the catalyst on at least a portion of the substrate, wherein the deposited catalyst is capable, upon exposure of the substrate on which the catalyst is deposited to a carbon nanotube precursor, of catalyzing the formation of vertically aligned carbon nanotubes on the substrate;
c) annealing the substrate on which the catalyst is deposited from b) in an inert atmosphere;
d) annealing the substrate from c) in a hydrogen gas atmosphere;
e) exposing the substrate from d) to an atmosphere comprising CNT precursor and an inert gas, thereby catalyzing formation, from the CNT precursor, of a plurality of vertically aligned carbon nanotubes, wherein each carbon nanotube of the plurality of vertically aligned carbon nanotubes has a substrate terminus and free terminus;
f) coating the substrate from e) with an inert filler material such that the free terminuses of the carbon nanotubes in the plurality remain exposed and the inert filler material forms a barrier on the substrate; and
g) removing the substrate and the deposited catalyst, thereby exposing the substrate terminuses of the plurality of carbon nanotubes, and thereby forming the free-standing membrane.

In other embodiments of the method and of the membrane, the substrate and deposited catalyst are not removed (e.g., membrane for use as an electrode).

### Substrates for Use in Making VANT Membranes

A variety of substrates can be used to make VANT membranes. Any substrate on which the VANT membrane can be formed and from which the VANT membrane can be isolated (e.g., by dissolution of the substrate or physical removal) can be used. The substrate can have a variety of sizes (e.g., length, width, and thickness). Examples of substrates that can be used include silicon (e.g., crystalline silicon substrates), quartz, ceramic, inorganic polycrystalline or crystalline materials, oxides, aluminum foil, and glass.

The substrate can be coated with an additional material. Without intending to be bound by any particular theory, it is considered that additional materials can provide, in various embodiments, a support for iron catalysts, can allow feed gases (e.g., ethylene) to reach the nanotube base and to be incorporated into the nanotube structure. It is considered that this pathway may be blocked (by the nanotubes themselves) if nanotubes are grown without a support layer.

For example, in an embodiment, the additional material is a metal or metal oxide and the substrate is coated with the metal or metal oxide. Examples of metals and metal oxides that can be used include, cobalt, molybdenum, aluminum, titanium, copper, nickel, manganese, alumina and manganese oxide.

In an embodiment, the substrate is silicon and the additional material is a metal oxide upon which the nanotubes are grown.

### Catalysts for Catalyzing CNT Formation

A variety of catalysts can be used. Any catalyst that, upon exposure to a CNT precursor (e.g., ethylene gas, acetylene gas, methane, or ethane) catalyzes the formation of carbon nanotubes can be used. Examples of catalysts that can be used include, but are not limited to, transition metals such as iron catalysts, e.g., elemental iron (e.g., an elemental iron film), cobalt, molybdenum, nickel, and yttrium, and mixtures or alloys thereof. The catalyst is disposed on the substrate (e.g., a substrate coated with an additional material) as, for example, a coating or as a film. In an embodiment, the catalyst is an iron film having a thickness of 1 nm to 25 nm. Mixtures or alloys of metals can be used. For example, a CoMo catalyst or a NiFe catalyst is used. Molecular catalysts comprising a metal or multiple metals can be used. An example of a molecular catalyst is an Fe-porphyrin catalyst.

### Annealing

Annealing is carried out, for example, to promote the relaxation of stresses in and/or the formation of catalyst sites (e.g., catalyst particles) from the catalyst coating or film. Annealing can be carried out in a variety of atmospheres and a variety of temperatures. For example, the annealing can be carried out in an inert atmosphere (e.g., argon or nitrogen), hydrogen, or a mixture thereof. The annealing atmosphere optionally comprises water. The annealing temperature is above the resting temperature of the material to be annealed (e.g., the substrate; the substrate and coating; the substrate, coating and catalyst) and below the melting temperature of the catalyst/support materials involved. Generally, lower annealing temperatures require longer annealing times. For example, the annealing can be carried out at temperatures of 30° C. to about the melting point of the materials present during the annealing.

In one embodiment, the substrate on which the catalyst is deposited is annealed in an inert atmosphere.

In another embodiment, the substrate on which the catalyst is deposited is annealed in a hydrogen gas atmosphere.

### Carbon Nanotube (CNT) Precursors

The carbon nanotubes are grown using a carbon nanotube (CNT) precursor. In an embodiment, the substrate (e.g., annealed substrate) is exposed to an atmosphere comprising CNT precursor and an inert gas, thereby catalyzing formation, from the CNT precursor, of a plurality of vertically aligned carbon nanotube.

The carbon nanotube precursor can be any molecule or gas that pyrolyzes to form carbon. The carbon nanotube precursor reacts to form carbon nanotubes on the substrate. Any gas that can decompose into elemental carbon at high temperature can be used as a carbon nanotube precursor. Examples of CNT precursors that can be used include, but are not limited to, ethylene, methane, acetylene, ethanol, and camphor. The substrate comprising a catalyst is contacted with a carbon nanotube precursor under conditions such that a plurality of vertically aligned nanotubes is formed. For example, ethylene is reacted at 800° C. The reaction temperature can be from about 500° C. to the melting temperature of the other materials present during carbon nanotube formation.

### Coating Inert Filler Material on Substrate

In an embodiment, the inert filler material is coated on the substrate on which vertically aligned CNTs have formed. The inert filler material can be coated in a variety of ways. Coating can include deposition of the inert filler (or a precursor of the inert filler), optionally, selective removal of the inert filler (or a precursor of the inert filler), and curing of the inert filler. For example, the material can be coated (e.g., deposited) by spin coating, dip coating, drop casting, and spray coating (e.g., using an aerosol based deposition).

In an embodiment, the inert filler is coated on the substrate such that the free terminuses (ends) of the carbon nanotubes are (or remain) exposed. For example, the inert material is an epoxy resin (an inert filler precursor) that is deposited on the substrate and the substrate subsequently contacted with a solvent that selectively removes one component (e.g., the cross-linking component) of the resin. In an embodiment, upon curing of the resin to form the coated inert filler material, the free terminuses (ends) of the carbon nanotubes remain exposed (i.e., are not covered by the epoxy resin).

The substrate (including any other materials such as support materials (e.g., alumina) can be removed in a variety of ways. Examples of suitable removal methods include dissolution, physical removal (e.g., physical abrasion), plasma treatment, thermal treatment, oxidation, or a combination thereof. For example, a crystalline silicon substrate is removed by dissolution in a hot base solution (e.g., hot 8M KOH) and the support material (e.g., alumina) is removed by physical abrasion.

The substrate terminuses of the carbon nanotubes can be exposed in a variety of ways. Examples of suitable methods include exposure to ozone or oxygen/argon plasma and mechanical abrasion. Substrate terminuses are exposed in embodiments in which the membrane is being used to transport protons or ions.

In another embodiment, the substrate terminus of the carbon nanotubes is not exposed (e.g., if the membrane is not being used for ion or proton transport).

The methods may also include functionalizing the membranes. For example, at least a portion of a surface of the carbon nanotubes is functionalized. The membranes can be functionalized with various functional groups or combinations of functional groups. The membranes can be functionalized with functional materials such as light absorbing molecules, catalytic molecules, proteins, or combinations thereof. The functionalization can be carried out by, for example, pi stacking, “Click chemistry”, or forming covalent bonds to acids on a CNT surface (e.g., amide bonds). Examples of suitable functionalization methods are known in the art. In embodiments, the nanotube is functionalized either before or after exposing the substrate terminus.

The methods described in the various embodiments and examples disclosed here are sufficient to produce VANT membranes. Thus, in an embodiment, the method comprises a combination of the steps of the methods disclosed herein.

### Devices Comprising VANT Membranes

The free-standing VANT membranes have a variety of uses that are based on the electron conduction and/or ion conduction properties of the VANT membranes.

In an embodiment, a device comprises a free-standing VANT membrane. For example, the device is a photoelectrochemical cell, a sieve, a sensor, or a filter (e.g., based on electrical interactions of filtrate with the CNTs or on exclusion of the filtrate by functional groups serving to selectively block CNT bore).

Suitable device structures are known in the art. In the case of a photoelectrochemical cell, the membrane is disposed between a water splitting region (characterized by water splitting catalysts and possibly photoacceptors) and a hydrogen production region (characterized by hydrogen production catalysts allowing flow of hydrogen ions and electrons from split water/photoacceptors to the hydrogen production region).

The following example(s) is offered by way of illustration and not by way of limitation.

### EXAMPLES

### Example 1

### Fabrication and Characterization of VANT Membranes

### Introduction

This example demonstrates fabrication and characterization of VANT membranes. The VANT membranes are hundreds of microns thick and demonstrate efficient electron conduction and proton transport through vertically aligned arrays of multi-walled carbon nanotubes (NTs) impregnated by chemically resistant epoxy. Electrical transport was Ohmic with a conductivity of 495 mS cm⁻¹. Protons traversed the membrane through the NT (carbon nanotube) bore with a current of 5.84×10⁻⁶ A. These membranes can be used in artificial photosynthesis and water splitting applications.

Carbon nanotubes (NTs) are an attractive alternative for a solar fuel membrane material as they are electrically conductive and provide an avenue for proton transport as well. It is well known that the extended pi structure of carbon nanotubes allows ballistic electron transport along their sidewalls, and that pristine NTs have outstanding electron conductivity. Additionally, positive and negative ions in solution can traverse the NT length through the bore especially when driven by an electrical potential. The ability to vary the NT diameter and functionalize the ends also means ionic transport through NTs could be controlled based on size exclusion and/or chemo-selectivity. Use of nanostructures as the basis for a membrane has the benefit of localizing transport properties into chemically distinct regions. These regions, as a result of the high surface area to volume ratio of NTs, are attractive attachment points for molecules that can perform other chemistries, such as catalysis.

This example demonstrates synthesis of freestanding, vertically aligned carbon nanotube (VANT) membranes, characterization their electron conductivity and proton transport, and demonstration of their successful use in an integrated system with colloidal CdSe quantum dots to generate photocurrents. By synthesizing NTs in a vertically aligned array, their excellent electron transport properties can direct electrons over micron distances. Vertical alignment also facilitates ion transport over long distances through the bore. The work described in this example demonstrated that proton and electron conducting membranes can be produced with complexity reductions compared to other nanostructured membranes, while maintaining efficient charge transport performance, thus providing new potential capabilities for solar fuel technologies.

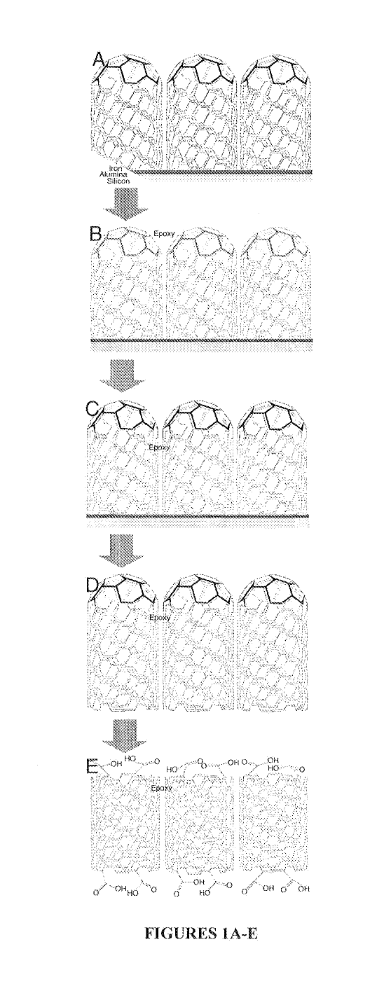

An embodiment of a general scheme for VANT membrane fabrication, which was used to fabricate the VANT membranes used in this example, is shown in FIGS. 1A-E, and comprises: NT growth, epoxy coating, and NT exposure.

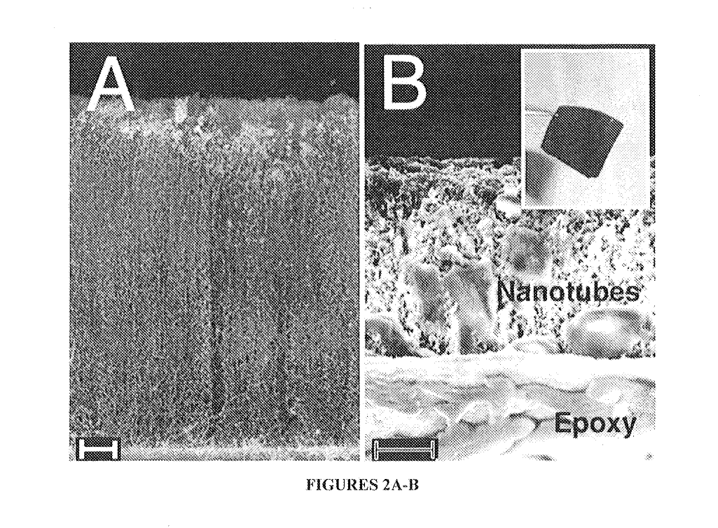

VANTs were grown via chemical vapor deposition on a crystalline silicon substrate in 2.5 cm diameter single opening tube furnace using variations of methods known in the art. Using electron beam evaporation, 10 nm of alumina support followed by 12 nm of iron catalyst were deposited onto a silicon wafer topped by 500 nm of thermal oxide. A square section of silicon wafer roughly 2.5 cm² was removed by etching with a diamond scribe followed by cleaving. The sample was placed in a quartz boat, introduced into a tube furnace, and heated to 800° C. under an argon atmosphere flowing at 595 sccm. Once at temperature, the catalyst was annealed under flowing hydrogen gas (13 sccm) for fifteen minutes, after which hydrogen flow was ceased and argon flow resumed. Ethylene gas was added (545 sccm) for another fifteen minutes to grow the NTs, which were subsequently cooled to room temperature under an argon atmosphere. An electron microscope image of the vertically aligned NTs is shown in FIG. 2A. The vertically aligned nanotube arrays grown via this process are multi-walled NTs, 100-150 μm tall, with 15-20 nm outer diameters, 5-10 nm inner diameters and with 15-20 walls.

As-grown carbon nanotube arrays are fragile and are unable to form a freestanding and robust membrane by themselves. Thus an inert filler material, commercially available, two-part epoxy, EPO-TEK® 301, was used to both fill the interstitial space between the NTs and to give the membrane rigidity. The inert filler material had several features. EPO-TEK® 301 was resistant to oxidation, and chemically inert to organic and polar solvents, inexpensive, commercially available (i.e., easy to obtain or manufacture), and amenable to solution based processing. Polystyrene and polydimethylsiloxane (PDMS) were also evaluated as possible inert filler materials and in various embodiments, can possibly be used as well.

The free-standing VANT membranes were formed by controlled impregnation of the VANTs with EPO-TEK® 301 (“epoxy”). The EPO-TEK® 301 was spin coated at 1000 rpm for 15 seconds onto the arrays where it filled the interstitial spaces between the nanotubes.

To transport protons and conduct electrons, the NT ends must be exposed and the end caps removed, as illustrated in FIG. 1C-E. To expose the NT tips above the epoxy, a few drops of isopropyl alcohol were spun at 800 rpm for 10 seconds onto a still-wet epoxy-coated VANT array. The cross linking agent (1,4-butanediol diglycidyl ether) is more soluble in alcohols than is the resin (1,6-diamino-2,2,4(2,4,4)-trimethylhexane). Thus, the addition of the alcohol dissolved some of the cross linker to a depth of 15-25 μm, allowing it to be spun off.

After curing at room temperature overnight, those areas lacking cross linker were uncoated by epoxy as shown in FIG. 2B. The silicon substrate was dissolved following epoxy impregnation by immersion in a hot 8 M KOH solution for approximately two hours, depicted in FIG. 1D. Removal of the substrate left behind the iron catalyst and alumina support, which block the NT bore and prevent proton transport. Both catalyst and support were removed by mechanical abrasion with 400 grit alumina sandpaper to visual inspection, followed by a five-minute immersion in concentrated hydrochloric acid [11 M].

In this manner, the substrate terminuses of the NTs (i.e., on the bottom of the membrane) were exposed as shown in FIG. 1D. Lastly the membrane was subjected to ozone treatment (FIG. 1E) to remove any fullerene caps on the top surface. This process also introduces carboxylate groups onto the nanotubes. The end result is a freestanding membrane containing open bored carbon nanotubes transversing the bulk and with exposed ends protruding from each surface (FIG. 2B Inset).

Electrical conduction and proton transport properties were evaluated separately. Resistance measurements were taken using a Hewlett Packard 4192A Impedance Analyzer. Samples with surface areas approximately 0.063 cm² were coated with 200 nm of gold contact via thermal evaporation before resistances were measured. The device resistance was 0.497Ω, corresponding to a conductivity of 495±12 mS cm⁻¹. These conductivities are ˜20 times higher than values for a previously reported silicon nanowire array/NAFION®/PEDOT-PSS membranes and ˜20 times lower than the best electron-conducting polymer films.

This improvement in resistivity compared to silicon nanowire array/NAFION®/PEDOT-PSS membrane is reasonable because the silicon nanowire array has a 7 μm pitch between conductive silicon nanorods. The pitch is nonconductive space, which lowers the number of potential electron pathways per area. In comparison, the VANT membranes have interstitial spaces on the order of 10 nm making for a much higher density of electron pathways. Other membranes incorporating vertically aligned carbon nanotube columns with a 400 μm pitch instead of full arrays also have much lower conductivities, approximately 1/1000^{th} of the values reported here. The loss in conductivity is again a result of the membrane having surface area and volume comprising non-electrically conductive material.

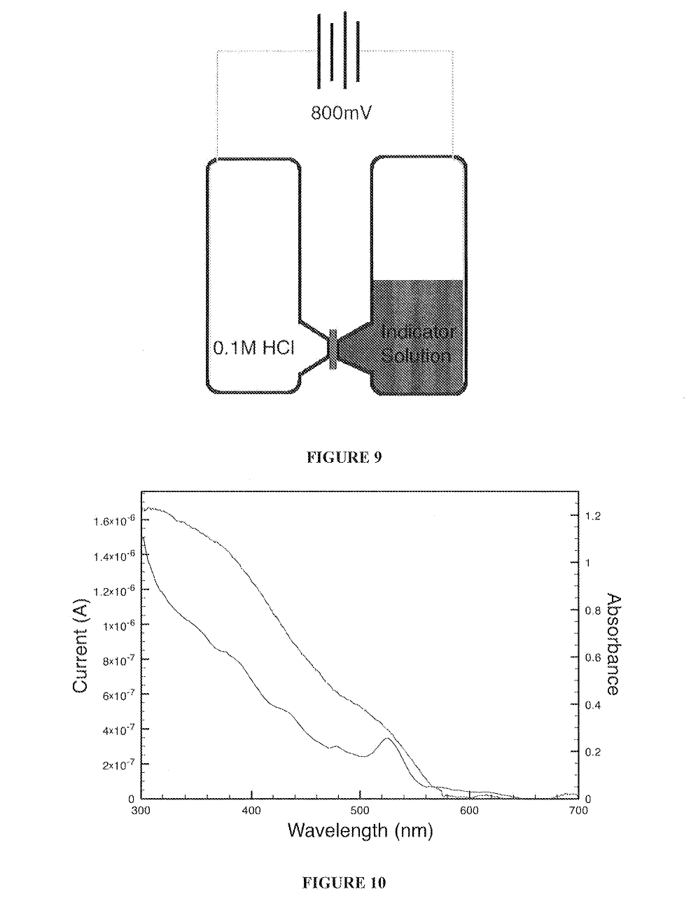

Proton transport through the membrane was characterized by monitoring the absorption spectrum of bromophenol blue, a common pH indicator, in the glassware system shown in FIG. 9. The membrane was placed between two vessels: one vessel contained 0.1 M HCl and the other an equal volume of 4 μM bromophenol blue indicator solution. Indicator concentration was chosen to account for the weaker absorption of the protonated indicator species. Acid and indicator volumes were kept equal to eliminate any pressure driven proton transport. Since protons cross through the membrane from the low pH to the high pH side, the concentrations of protonated and deprotonated indicator species changed, which was quantified by a Beer's Law analysis of the absorption spectrum.

The VANT membrane, with an area of 0.38 cm² exposed to each solution, was presoaked in deionized water for 48 hours before the crossing experiment to allow water to infiltrate the nanotube bores and establish a conduit for proton transport. A 0.8 V potential difference was placed across the apparatus, which served to drive positively charged hydrogen ions across the membrane, preclude crossing by negatively charged chlorine anions, and supply electrons to balance charge across the membrane.

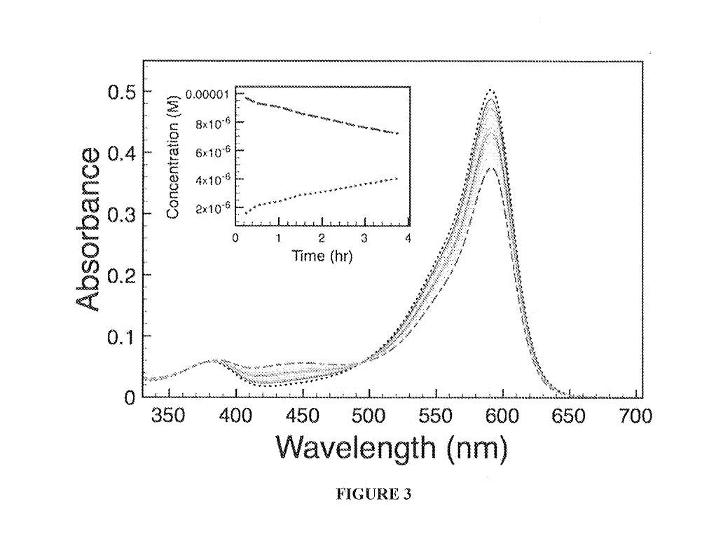

The spectral changes associated with protons crossing the membrane are shown in FIG. 3. The peak at 593 nm (absorption by the deprotonated indicator) decreases as the peak at 449 nm (absorption by the protonated species), increases proportionally indicating that protons were crossing through the NT membrane. Proton population on the indicator side increases linearly with time (FIG. 3 Inset) and corresponds to an average proton current of 5.84×10⁻⁶ A. The proton current in the VANT membranes is an order of magnitude greater than those measured in unaligned mats of carbon NTs, even when correcting for differences in applied voltage and membrane geometries. The data is consistent with the improvement owing to the greater NT density and orientation control gained by using aligned NT arrays as a membrane basis compared to a disordered NT/epoxy mixture.

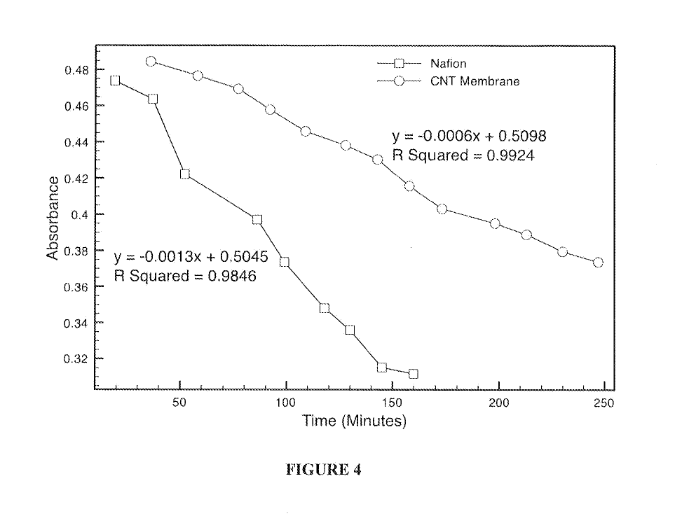

The proton current through a 125 μm NAFION® film was measured in an identical experiment to that used to evaluate the VANT membranes. Proton crossing, as depicted in FIG. 4, was approximately 2 times faster in the NAFION film than in the VANT membrane.

Untreated NAFION® is reported to have a proton conductivity of 78 mS cm⁻¹, similar to that reported for silicon/NAFION®/PEDOT-PSS membranes, roughly 4 times that of reported PEDOT:sPSS membranes and 9 times that of a mixed VANT column/NAFION® membrane despite serving NAFION® as the proton transport material. Additionally, because proton transport in the VANT membrane only occurs through the carbon NT bore, the active area for proton transport in the VANT membrane is less than the NAFION® film. However, a direct comparison to published membranes and a proton conductivity value are inappropriate for the VANT membrane. NTs do not conduct protons, but rather can provide a means for their transport. As a consequence of this lack of conductivity (and therefore resistivity), VANT membranes do not contribute resistance to proton flow beyond what is termed the electrolyte resistance (R_{elec}) as discussed in the published literature. A membrane such as the silicon/NAFION®/PEDOT-PSS membrane, a PEDOT:sPSS membrane, or NAFION® itself, has a characteristic device resistance (Rₘₑₘ) caused by the proton transport material (NAFION®, sPSS) in addition to the electrolyte resistance, thus decreasing the net ionic current through the material (R_{cell}=Rₘₑₘ+R_{elec}). Increasing NT density would increase both proton transport and electron conductivity by providing more pathways per membrane area.

As a proof-of-principle demonstration of the applicability of VANT membranes to solar fuel production, CdSe quantum dots (QDs), were placed onto a VANT membrane forming a photoelectrochemical cell (FIG. 5).

The QDs were synthesized in a mixed hexanes solution which was dripped onto the NT array surface. The hexanes were allowed to evaporate, leaving behind a QD film attached to the NT array. Upon photoexcitation of the QDs, electrons were transferred through the NT array to an electrode attached to the bottom of the array. A 0.1 M solution of ascorbic acid served as a sacrificial electron donor and replenished the lost electrons on the QDs. The QD/NT system was irradiated with 440 nm light and the resulting photocurrent was detected using a CH Instruments Electrochemical Analyzer potentiostat. Unblocking and blocking the light source results in the jumps in photocurrent shown in FIG. 5.

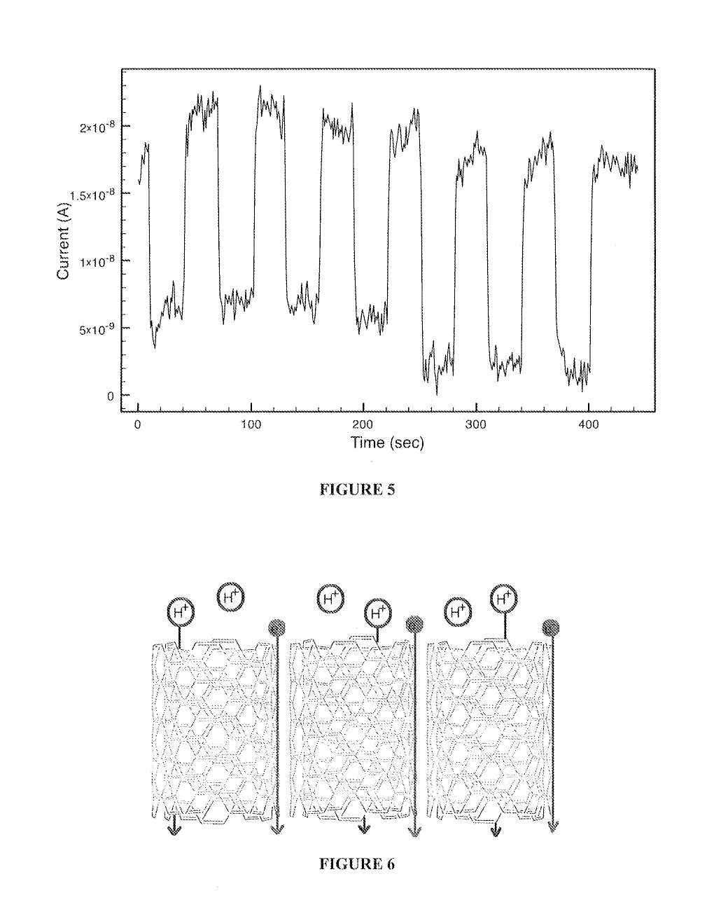

FIG. 6 shows a graphical representation of function of VANT membrane.

VANT membranes have great promise for potential applications in artificial photosynthesis. First, carbon is inexpensive and readily available, which is advantageous if there is to be any large-scale implementation of water splitting systems as an energy solution.

Second, although not quantified, the membranes in this example also display toughness, both chemical and physical. The fabrication process requires the membranes survive extended contact with both hot, concentrated base (8 M KOH at ˜398K) and concentrated acid (11 M HCl). Membranes also withstand the mechanical stress of abrading away the iron catalyst and alumina support. Following all these treatments, the membranes remain whole, flexible and easily manipulated by hand.

Third, fabrication of the membranes is simple, using only one material, carbon nanotubes, for both electron conduction and proton transport. In the case of art-known silicon nanowire arrays and VANT columns, fabrication uses photolithography steps before deposition of catalysts for array growth and the use of hydrofluoric acid. Growth of carbon nanotube arrays by contrast, uses only the (unpatterned) catalyst deposition before growth. Also, no secondary transport material, such as NAFION®/sPSS is required for fabrication of the VANT membranes. This yields a reduction in complexity as well as an increase in electron and proton conductivity.

Fourth, the VANT membranes provide large surface area and chemical selectivity for the attachment of light absorbing or catalytic molecules, such as those involved in water splitting. As fabricated, the VANT membranes leave the nanotube pi system available not just for electron transport, but also for potential chemical modification. This makes them adaptable to use as sieves, sensors, electrodes or other applications. Mixed polymer systems without nano-scaffolds, while displaying excellent conductive properties, have limited functionality in this regard, owing to their low surface roughness.

In summary, this example demonstrates a simple, two-component VANT membrane based on vertically aligned carbon nanotube arrays and commercially available epoxy. The VANT membrane is capable of conducting electrons and provides means for the transport of protons and electrons. Additionally the VANT membranes display other desirable characteristics including low cost, excellent durability (both chemical and physical), macroscale size and the potential to incorporate other chemistries. This collection of properties results directly from the nature of carbon nanotubes. The advances demonstrated in this example, together with the potential increased electrical and proton transport through membranes based on higher density NT arrays, and the chemical and physical properties of nanotubes, form a compelling platform for future development.

### Materials and Methods

### Carbon Nanotube Synthesis.

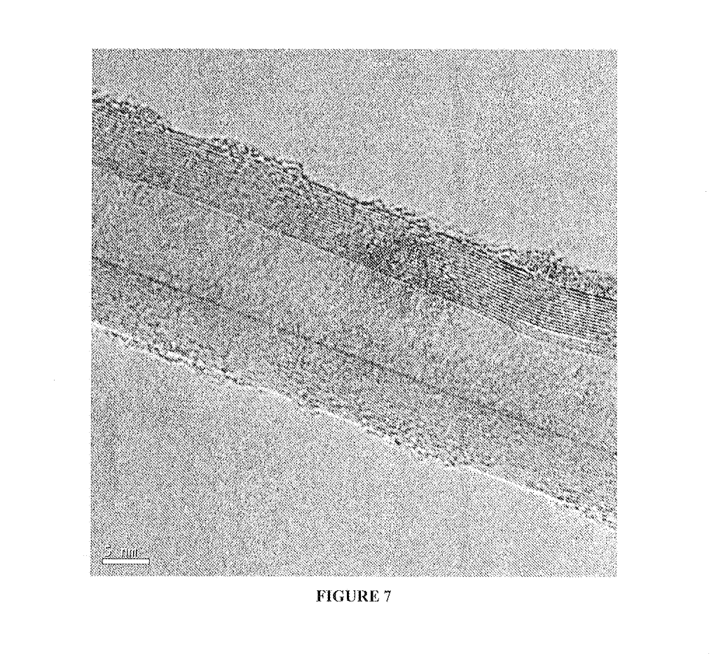

Carbon nanotube synthesis was performed via chemical vapor deposition (CVD) in a single join quartz tube furnace (design, schematic) 25 mm in diameter and 400 mm long. Before synthesis, silicon wafers with 500 nm thermal oxide (Ultrasil Corporation, Hayward Calif.) were coated with 10 nm of alumina followed by 12 nm of iron at a rate of 2 Å/s using an electron beam deposition system. FIG. 7 is a TEM image of an individual as grown multi-walled nanotube. Numerous sidewalls (15-20 nm) are visible. Silicon substrates roughly 2.5 cm² were placed in a quartz boat 2.5 cm×10 cm×1.75 cm and loaded into the tube furnace. Typical synthesis is as follows. First the furnace was brought up to 800° C. under argon (Airgas 99.997%) flowing at 595 sccm. Second argon was turned off and hydrogen gas (Airgas 99.95%) at 13 sccm was flowed through the system for 15 minutes. Third argon flow was restored, still at 595 sccm, and growth was carried out using ethylene (Airgas 99.995%) as a carbon source at 545 sccm for another fifteen minutes. Ethylene was then shut off and the system was allowed to cool to room temperature under 595 sccm argon flow.

Following nanotube growth, the arrays were spin coated with EPO-TEK 301® (“epoxy”) (Conservation Resources LLC, Sacramento, Calif.) prepared in a 4:1 mixture of resin and cross linker per manufacturer's instructions. Roughly 1 mL of mixed epoxy was pipetted onto an array. The array was then spun at 1000 rpm for 15 seconds, resulting in complete coverage of the array with epoxy. Roughly 1 mL of solvent grade isopropyl alcohol was then placed on the array. The array was spun at 800 rpm for 10 seconds. A second 1 mL aliquot of isopropyl alcohol was applied, followed by a final spin at 800 rpm for 10 seconds. The epoxy coated arrays were placed in a dying furnace at 125 ° C. for 15 minutes prior to being left overnight to cure at room temperature. Ozone treatment was performed in a Bioforce Nanosciences UV Ozone cleaner for 10 minutes per side.

### Electrical Conduction.

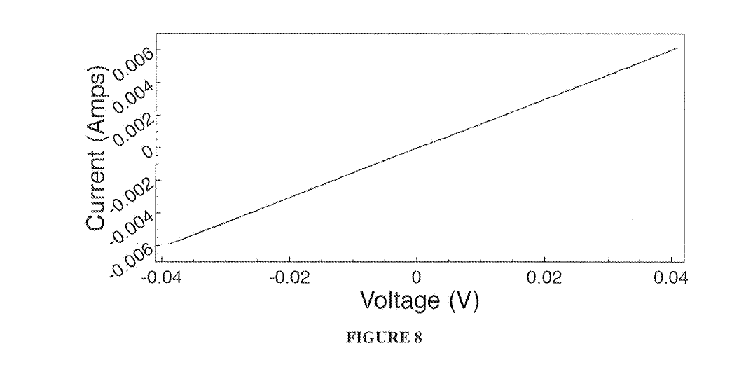

Samples were then thoroughly washed with deionized (DI) water, then allowed to dry for 48 hours prior to electrical measurements. Electrical measurements were performed on a Hewlett Packard 4192A Impedance Analyzer. The ohmic nature of electrical conduction through the membranes was confirmed by current vs. voltage measurements taken in the same direction as the long VANT axis, over a dynamic range of three orders of magnitude. (FIG. 8). These measurements were taken using a Stanford Research Systems SR570 Low Noise Current Preamp and a custom Labview control module. While individual carbon nanotubes themselves are capable of transporting electrons ballistically, membranes fabricated from nanotube arrays have many contacts between NTs and thus are expected to conduct according to Ohm's law. Indeed, as shown in FIG. 8 the current-voltage relationship was linear with a resistance through the membrane of 6.65Ω The measurement was performed three times, all of which are shown in FIG. 8. Error bars are smaller than the points used to plot the data. This resistance figure overestimates the actual device resistance because of difficulty achieving a robust electrical contact between the sample and the instrument.

### Proton Crossing.

Prior to the proton crossing experiments. VANT membranes were immersed in DI water for 48 hours. Proton crossing was evaluated using bromophenol blue (Fischer Scientific). Several other indicators active in the appropriate pH range of 3-5 (methyl red, Congo red, methyl orange and a universal indicator solution—Fisher Scientific) were also evaluated and found to spontaneously deprotonate during the experimental time frame. Proton crossing experiments were performed as described in a specially designed glassware apparatus, as depicted in FIG. 9.

### Chromophore Interactions.

To confirm that peak photocurrent generation occurs with peak quantum dot absorbance the QD/NT system was irradiated from 300 to 700 nm while current was monitored. The results, shown in FIG. 10, clearly show current (top curve) rising at quantum dot absorbance peaks (bottom curve) Like the data in FIG. 5 these measurements were made in a 0.1 M solution of ascorbic acid. Current is measured against a saturated calomel electrode. Absolute current means little as it reflects aggregation of charged species in solution around the working and counter electrodes. Photocurrent in FIG. 10 and FIG. 5 are best considered as deviations from baseline current level.

### Samples of Devices and Methods

A sample of the membranes, devices and methods that are described herein is set forth in the following numbered paragraphs:

1. A free-standing membrane comprising:
a plurality of vertically aligned carbon nanotubes, each of the plurality of vertically aligned carbon nanotubes having:
   a first terminus at a first side of the membrane,
   a second terminus at a second side of the membrane, wherein the first terminus and the second terminus are exposed,
   a length of at least 1 nm, and
   an inner diameter of 0.13 nm to 100 nm; and
   a non-conducting, inert filler material disposed in interstitial space between the nanotubes such that a barrier is formed, wherein the membrane has a thickness between 1 nm and 1 cm.

2. The membrane of paragraph 1, wherein the membrane simultaneously conducts electrons and transports ions.

3. The membrane of paragraph 2, wherein the ions are protons, potassium ions, or lithium ions.

4. The membrane of paragraph 1, wherein the membrane has an area of 5 nm² to 300 cm².

5. The membrane of paragraph 1, wherein the membrane has a length of 5 nm to 50 cm and/or a width of 5 nm to 50 cm.

6. The membrane of paragraph 1, wherein at least a portion of a surface of at least one of the vertically aligned nanotubes has disposed thereon functional groups selected from the group consisting of carboxylic acid groups, acyl halides (e.g., acyl chloride), esters, anhydrides, ketones, and combinations thereof.

7. The membrane of paragraph 1, wherein at least a portion of a surface of at least one of the vertically aligned nanotubes has immobilized thereon at least one light absorbing material (e.g., a light absorbing molecule), catalytic material (e.g., a catalytic molecule), or a combination thereof.

8. A device comprising the free-standing membrane of paragraph 1.

9. The device of paragraph 8, wherein the device is a photoelectrochemical cell, a sieve, a sensor, or a filter.

10. A method for making a free-standing membrane comprising:
a) providing a catalyst and a substrate;
b) depositing the catalyst on at least a portion of the substrate, wherein the deposited catalyst is capable, upon exposure of the substrate on which the catalyst is deposited to a carbon nanotube precursor, of catalyzing the formation of vertically aligned carbon nanotubes on the substrate;
c) annealing the substrate on which the catalyst is deposited from b) in an inert atmosphere;
d) annealing the substrate from c) in a hydrogen gas atmosphere;
e) exposing the substrate from d) to an atmosphere comprising CNT precursor and an inert gas, thereby catalyzing formation, from the CNT precursor, of a plurality of vertically aligned carbon nanotubes, wherein each carbon nanotube of the plurality of vertically aligned carbon nanotubes has a substrate terminus and free terminus;
f) coating the substrate from e) with an inert filler material such that the free terminuses of the carbon nanotubes in the plurality remain exposed and the inert filler material forms a barrier on the substrate; and
g) removing the substrate and the deposited catalyst, thereby exposing the substrate terminuses of the plurality of carbon nanotubes, and thereby forming the free-standing membrane. In other embodiments, the substrate and deposited catalyst are not removed (e.g., for use as an electrode).

11. The method of paragraph 10, comprising functionalizing at least a portion of a surface of a carbon nanotube in the plurality. In various embodiments, the functionalizing of at least a portion of a surface of a carbon nanotube in the plurality can occur before or after removing the substrate and deposited catalyst.

12. The method of paragraph 10, wherein the membrane simultaneously conducts electrons and transports ions.

13. The method of paragraph 12, wherein the ions are protons, potassium ions, or lithium ions.

14. The method of paragraph 10, wherein the membrane has an area of 5 nm² to 300 cm².

15. The method of paragraph 10, wherein the membrane has a length of 5 nm to 50 cm and/or a width of 5 nm to 50 cm.

16. The method of paragraph 10, wherein at least a portion of a surface of at least one of the vertically aligned nanotubes has disposed thereon functional groups selected from the group consisting of carboxylic acid groups, acyl halides (e.g., acyl chloride), esters, anhydrides, ketones, and combinations thereof.

17. The method of paragraph 10, wherein at least a portion of a surface of at least one of the vertically aligned nanotubes has immobilized thereon at least one light absorbing material (e.g., a light absorbing molecule), catalytic material (e.g., a catalytic molecule), or a combination thereof.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

While embodiments of the present disclosure have been particularly shown and described with reference to certain examples and features, it will be understood by one skilled in the art that various changes in detail may be effected therein without departing from the spirit and scope of the present disclosure as defined by claims that can be supported by the written description and drawings. Further, where exemplary embodiments are described with reference to a certain number of elements it will be understood that the exemplary embodiments can be practiced utilizing either less than or more than the certain number of elements.

All references cited herein are incorporated herein by reference in their entirety and for all purposes to the same extent as if each individual publication, patent or patent application was specifically and individually indicated to be incorporated by reference in its entirety for all purposes.

The citation of any publication is for its disclosure prior to the filing date and should not be construed as an admission that the present invention is not entitled to antedate such publication by virtue of prior invention.

What is claimed is:

1. A free-standing membrane comprising:
a plurality of vertically aligned carbon nanotubes, each of the plurality of vertically aligned carbon nanotubes having:
a first terminus at a first side of the membrane,
a second terminus at a second side of the membrane, wherein the first terminus and the second terminus are exposed,
a length of at least 1 nm, and
an inner diameter of 0.13 nm to 100 nm; and
a non-conducting, inert filler material disposed in interstitial space between the nanotubes such that a barrier is formed, wherein the membrane has a thickness between 1 nm and 1 cm.

2. The membrane of claim 1, wherein the membrane simultaneously conducts electrons and transports ions.

3. The membrane of claim 2, wherein the ions are protons, potassium ions, or lithium ions.

4. The membrane of claim 1, wherein the membrane has an area of 5 nm² to 300 cm².

5. The membrane of claim 1, wherein the membrane has a length of 5 nm to 50 cm and/or a width of 5 nm to 50 cm.

6. The membrane of claim 1, wherein at least a portion of a surface of at least one of the vertically aligned nanotubes has disposed thereon functional groups selected from the group consisting of carboxylic acid groups, acyl halides, esters, anhydrides, ketones, and combinations thereof.

7. The membrane of claim 1, wherein at least a portion of a surface of at least one of the vertically aligned nanotubes has immobilized thereon at least one light absorbing material, catalytic material, or a combination thereof.

8. A device comprising the free-standing membrane of claim 1.

9. The device of claim 8, wherein the device is a photoelectrochemical cell, a sieve, a sensor, or a filter.

10. A method for making a free-standing membrane comprising:
a) providing a catalyst and a substrate;
b) depositing the catalyst on at least a portion of the substrate, wherein the deposited catalyst is capable, upon exposure of the substrate on which the catalyst is deposited to a carbon nanotube precursor, of catalyzing the formation of vertically aligned carbon nanotubes on the substrate;
c) annealing the substrate on which the catalyst is deposited from b) in an inert atmosphere;
d) annealing the substrate from c) in a hydrogen gas atmosphere;
e) exposing the substrate from d) to an atmosphere comprising carbon nanotube (CNT) precursor and an inert gas, thereby catalyzing formation, from the CNT precursor, of a plurality of vertically aligned carbon nanotubes, wherein each carbon nanotube of the plurality of vertically aligned carbon nanotubes has a substrate terminus and free terminus;
f) coating the substrate from e) with an inert filler material such that the free terminuses of the carbon nanotubes in the plurality remain exposed and the inert filler material forms a barrier on the substrate; and
g) removing the substrate and the deposited catalyst, thereby exposing the substrate terminuses of the plurality of carbon nanotubes, and thereby forming the free-standing membrane.

11. The method of claim 10, comprising functionalizing at least a portion of a surface of a carbon nanotube in the plurality.

12. The method of claim 10, wherein the membrane simultaneously conducts electrons and transports ions.

13. The method of claim 12, wherein the ions are protons, potassium ions, or lithium ions.

14. The method of claim 10, wherein the membrane has an area of 5 nm² to 300 cm².

15. The method of claim 10, wherein the membrane has a length of 5 nm to 50 cm and/or a width of 5 nm to 50 cm.

16. The method of claim 10, wherein at least a portion of a surface of at least one of the vertically aligned nanotubes has disposed thereon functional groups selected from the group consisting of carboxylic acid groups, acyl halides, esters, anhydrides, ketones, and combinations thereof.

17. The method of claim 10, wherein at least a portion of a surface of at least one of the vertically aligned nanotubes has immobilized thereon at least one light absorbing material, catalytic material, or a combination thereof.
